(19) United States
(12) Patent Application Publication
(10) Pub. No.: US 2020/0152586 A1
(43) Pub. Date: May 14, 2020

(54) ELECTRONIC DEVICE INCLUDING AN ELECTRONIC CHIP AND AN ANTENNA

(71) Applicant: STMicroelectronics (Grenoble 2) SAS, Grenoble (FR)

(72) Inventor: Didier CAMPOS, Charavines (FR)

(73) Assignee: STMicroelectronics (Grenoble 2) SAS, Grenoble (FR)

(21) Appl. No.: 16/680,134

(22) Filed: Nov. 11, 2019

(30) Foreign Application Priority Data
Nov. 14, 2018 (FR) 1860504

(51) Int. Cl. H01L 23/66; H01L 23/31; H01L 23/498; H01L 23/00; H01Q 1/38; H01Q 1/22

(52) U.S. Cl. CPC H01L 23/66; H01L 23/3121; H01L 23/49822; H01L 23/49833; H01L 23/49838; H01L 24/48; H01L 2224/16227; H01Q 1/38; H01Q 1/2283; H01L 24/16; H01L 2223/6677; H01L 2224/32225; H01L 2224/48227; H01L 24/32

(57) ABSTRACT

A carrier substrate includes an integrated network of electrical connections extending from a front face to a back face. An electromagnetic antenna is located on the front face of the carrier substrate and is connected to the integrated network. An electronic chip is mounted over the front face of the carrier substrate, and connected to the integrated network, at a location offset from the antenna. An encapsulation layer encapsulates the electronic chip. The encapsulation layer includes, recessed with respect to its front surface, a local void that is located laterally away from the electronic chip and extends over a zone that at least partly covers the location of the electromagnetic antenna.

### PRIORITY CLAIM

This application claims the priority benefit of French Application for Patent No. 1860504, filed on Nov. 14, 2018, the content of which is hereby incorporated by reference in its entirety to the maximum extent allowable by law.

### TECHNICAL FIELD

Embodiments relate to electronic devices that include electromagnetic antennas.

### SUMMARY

According to one embodiment, an electronic device comprises a carrier substrate having a front face and a back face and including an integrated network of electrical connections from one face to another face and an electromagnetic antenna that is located on the front face side and in a zone thereof and is connected to said network of electrical connections; an electronic chip that is mounted on top of the front face of the carrier substrate in a zone thereof, which chip is connected to said network of electrical connections, the antenna and the chip being located in distinct zones of the front face of the carrier substrate; and a layer at least partially encapsulating the chip, formed on top of the front face of the carrier substrate and having a front face.

Advantageously, the encapsulation layer has, recessed with respect to its front face, at least one local void that is located laterally away from the chip and extends over at least one zone that at least partly covers the zone of the antenna.

Thus, the effects, which are caused by the layer encapsulating the chip, of attenuating and/or interfering with the electromagnetic signals emitted and/or received by the antenna are limited by virtue of the presence of the local void made in the encapsulation layer.

The local void may extend down through part of the thickness of the encapsulation layer.

The local void may extend down through the entire thickness of the encapsulation layer, to the front face of the carrier substrate.

The encapsulation layer may cover the chip.

The front face of the encapsulation layer may be parallel to the front face of the carrier substrate.

The encapsulation layer may be molded.

A process for fabricating the electronic device, comprises the following steps: placing the carrier substrate provided with the electronic chip in a cavity of a mold, this cavity having a face that is located facing the front face of the carrier substrate; injecting an encapsulation material into the cavity of the mold so as to produce the layer encapsulating the chip; removing the obtained intermediate device from the mold; and producing said local void by removing material from the encapsulation layer.

Another process for fabricating the electronic device is also proposed, which process comprises the following steps: placing the carrier substrate provided with the electronic chip in a cavity of a mold, this cavity having a face that is located facing the front face of the carrier substrate, provided with at least one part protruding in the direction of the front face of the carrier substrate and located laterally and away from the chip; injecting an encapsulation material into the cavity of the mold so as to produce a layer encapsulating the chip, this layer having, at the site of said part protruding from the mold, said local void; and removing the obtained device from the mold.

### BRIEF DESCRIPTION OF THE DRAWINGS

An electronic device will now be described by way of non-limiting exemplary embodiment, illustrated by the drawing, in which:

FIG. 1 shows a cross section of an electronic device; and

FIG. 2 shows a view from above of the electronic device of FIG. 1, along the section II-II.

### DETAILED DESCRIPTION

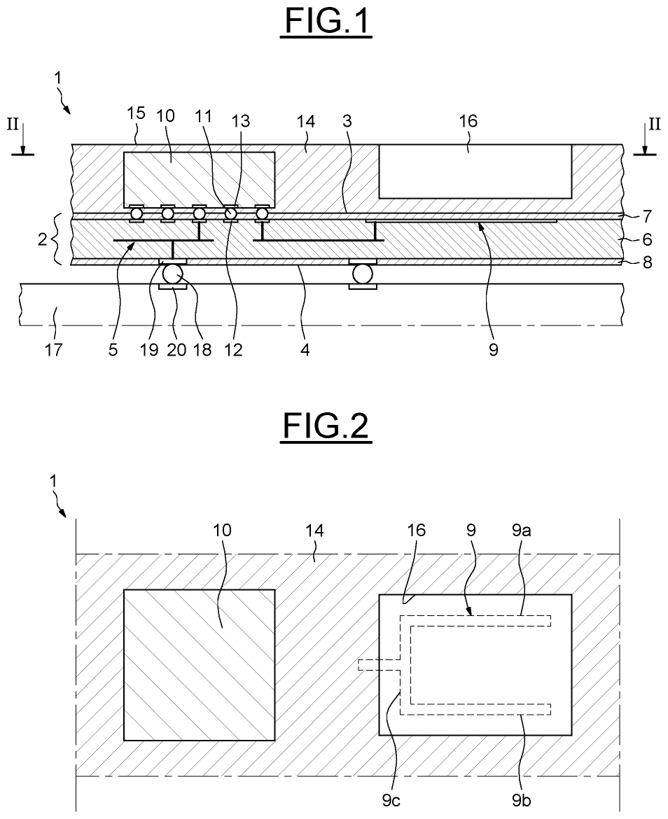

As illustrated in FIGS. 1 and 2, an electronic device 1 comprises a carrier substrate 2, in the form of a wafer, having a front face 3 and a back face 4 and including an integrated network of electrical connections 5 from the front face to the back face.

The integrated network of electrical connections 5 may comprise front and back metal levels that are located on either side of a core 6 of the carrier substrate 2, wherein the core is made of a dielectric material. The front and back metal levels are electrically connected by metal vias passing through the core. The integrated network of electrical connections 5 may further comprise one or more intermediate metal levels that are located between layers of the core of the carrier substrate 2, the intermediate metal levels being electrically connected to each other and to the front and back metal levels by metal vias.

The carrier substrate 2 further comprises a front passivation layer 7 and a back passivation layer 8, where the passivation layers are located on either side of the core 6 and are made of a dielectric material.

The carrier substrate 2 further includes an electromagnetic antenna 9 that is located on the front face 3 side and is connected to the network of electrical connections 5. The antenna 9 is formed flat in the front metal level of the network of electrical connections 5, under the front passivation layer 7. The antenna 9 comprises branches and is formed in a zone of the front face 3 of the carrier substrate 2, which zone is circumscribed by these branches.

For example, as illustrated in FIG. 2, the antenna 9 takes the shape of a fork and comprises two parallel branches 9a and 9b that are a short distance away from one another, and are connected to one another by a transverse branch 9c that is connected to the network of electrical connections 5. In this case, the zone in which the antenna 9c is formed is rectangular.

The electronic device 1 comprises an electronic integrated circuit chip 10 that is mounted on top of the front face 3 of the carrier substrate 2 and is connected to the network of electrical connections 5. The electronic chip 10 is configured for handling radiofrequency signals.

The antenna 9 and the chip 10 are located in distinct zones of the front face 3 of the carrier substrate 2.

The chip 10 is connected to the network of electrical connections 5 via electrical connection elements 11 that are interposed between the carrier substrate 2 and the chip 10. The electrical connection elements 11 are placed on front pads 12 of the network of electrical connections 5, through the front passivation layer 7 and under pads 13 of the chip 10.

However, the chip 10 could be connected to the network of electrical connections 5 by electrical wires connected to pads of the carrier substrate 2 that are located on the periphery and away from the chip 10. In this case, the zone occupied by the chip 10 includes these pads.

The electronic device 1 comprises an encapsulation layer 14, made of a dielectric material, on top of the front face 3 of the carrier substrate 2, in which the chip 10 is at least partially embedded and which has an outer face 15.

The outer face 15 of the encapsulation layer 14 runs parallel to the front face 3 of the carrier substrate 2 and covers a surface (for example, the front or back surface) of the chip 10 or is flush with a surface (for example, the back surface) of the chip 10.

The encapsulation layer 14 has, recessed with respect to the front face 15, at least one local void 16 that is located away from the zone where the chip 10 is located and extends over at least one zone that at least partly covers the zone of the antenna 9.

In the aforementioned case of a fork-shaped antenna 9, the local void 16 may have a rectangular periphery inside which the zone of the antenna 9 is located, the branches 9a and 9b being inside the zone of the local void 16 and being parallel to two opposite sides of the local void 16.

The local void 16 extends down through at least part of the thickness of the encapsulation layer 14, or extends through the entire thickness of the encapsulation layer to reach the front face 3 of the carrier substrate 2 at passivation layer 7.

Thus, the encapsulation layer 14, which is provided to coat the chip 10, does not form an obstacle to, or limit the effects by attenuating and/or interfering with, the emission and/or reception of electromagnetic signals by the antenna 9 by virtue of the presence of the local void 16.

The electronic device 1 may be mounted on a printed circuit board 17, via electrical connection elements 18 that are interposed between the back pads 19 of the network of electrical connections 5 of the carrier substrate 2 and the pads 20 of the printed circuit board 17.

According to one variant embodiment, the electronic device may be obtained in the following manner.

The carrier substrate 2 provided with the chip 10 is placed in a cavity of a two-part mold, this cavity having a face that is located facing the front face 3 of the carrier substrate 2 and is away from or makes contact with the chip 10.

Next, an encapsulation material is injected into the cavity of the mold so as to produce an encapsulation layer 14, of constant thickness, encapsulating the chip 10.

After removing the obtained intermediate device from the mold, the local void 16 is produced by locally removing material from the layer 16, so as to obtain the electronic device 1. The material may be removed by mechanically and/or chemically attacking the material of the encapsulation layer 14.

According to another variant embodiment, the electronic device may be obtained in the following manner.

The carrier substrate provided with the chip 10 is placed in a cavity of a two-part mold, this cavity having a face defined by one part of the two-part mold that is located facing the front face 3 of the carrier substrate 2, said face being provided with a local part that protrudes in the direction of the front face 3 of the carrier substrate 2 and which is located laterally and away from the chip 10. The end face of the protruding part makes contact with or is a short distance away from the front face 3 of the carrier substrate 2.

Next, an encapsulation material is injected into the cavity of the mold so as to produce a layer 14 encapsulating the chip 10, this encapsulation layer 14 directly having, at the site of said part protruding from the mold, the local void 16. Next, the directly obtained electronic device 1 is removed from the mold.

1. An electronic device, comprising:
a carrier substrate having a front face and a back face and including an integrated network of electrical connections from the front face to the back face and comprising a front metal level and a rear metal level;
an electromagnetic antenna that is formed from the front metal level and located on the front face in a first zone of the carrier substrate and is connected to said network of electrical connections;
an electronic chip that is mounted over the front face of the carrier substrate in a second zone of the carrier substrate, said electronic chip being connected to said network of electrical connections, wherein the second zone is separate from the first zone; and
an encapsulation layer which at least partially encapsulates the chip and is formed over the front face of the carrier substrate, said layer having a front surface; and
wherein the encapsulation layer has, recessed with respect to the front surface, at least one local void that is located laterally away from the chip and extends over at least the first zone where the electromagnetic antenna is located.

2. The electronic device according to claim 1, wherein the local void extends from the front surface only partially through a thickness of the encapsulation layer.

3. The electronic device according to claim 1, wherein the local void extends from the front surface completely through a thickness of the encapsulation layer.

4. The electronic device according to claim 1, wherein the encapsulation layer covers the electronic chip.

5. The electronic device according to claim 1, wherein the front face of the encapsulation layer is parallel to the front face of the carrier substrate.

6. The electronic device according to claim 1, wherein the encapsulation layer is molded.

7. The electronic device according to claim 1, further including a passivation layer between the encapsulation layer and the carrier substrate, and wherein the electromagnetic antenna is located underneath the passivation layer.

8. The electronic device according to claim 1, wherein the integrated network of electrical connections includes connection pads formed from the front metal level at the first face, and wherein the electromagnetic antenna is located at a same level as the connection pads.

9. The electronic device according to claim 1, wherein the at least one local void has side edges and wherein elements of the electromagnetic antenna extend parallel to the side edges.

10. A process for fabricating an electronic device, comprising:
placing an assembly in a cavity of a two-part mold, wherein the assembly is made of a carrier substrate, an electronic chip mounted to the carrier substrate, and a surface electromagnetic antenna formed in a front metal layer of the carrier substrate, wherein the cavity is defined by a face of one part of the two-part mold that is located facing a front face of the carrier substrate;
injecting an encapsulation material into the cavity of the mold so as to produce an encapsulation layer which encapsulates the electronic chip;
removing an intermediate device from the mold, said intermediate device including the carrier substrate, electronic chip, surface electromagnetic antenna and encapsulation layer;
removing material from the encapsulation layer to produce a local void located laterally away from the electronic chip and extending over a zone where the surface electromagnetic antenna is located.

11. The process according to claim 10, wherein the local void extends from a front surface of the encapsulation layer only partially through a thickness of the encapsulation layer.

12. The process according to claim 10, wherein the local void extends from a front surface of the encapsulation layer completely through the thickness of the encapsulation layer.

13. The process according to claim 10, wherein the encapsulation layer covers the electronic chip.

14. The process according to claim 10, wherein the local void has side edges and wherein elements of the surface electromagnetic antenna extend parallel to the side edges.

15. A process for fabricating an electronic device, comprising:
placing an assembly in a cavity of a two-part mold, wherein the assembly is made of a carrier substrate, an electronic chip mounted to the carrier substrate, and a surface electromagnetic antenna formed in a front metal layer of the carrier substrate, wherein the cavity is defined by a face of one part of the two-part mold that is located facing a front face of the carrier substrate and which includes at least one part protruding in the direction of the front face of the carrier substrate and located laterally and away from the electronic chip;
injecting an encapsulation material into the cavity of the mold so as to produce an encapsulation layer which encapsulates the electronic chip, the encapsulation layer having, at zone where the electromagnetic antenna is located, a local void;
removing the electronic device including the carrier substrate, mounted electronic chip, surface electromagnetic antenna and encapsulation layer with local void from the mold.

16. The process according to claim 15, wherein the local void extends from a front surface of the encapsulation layer only partially through a thickness of the encapsulation layer.

17. The process according to claim 15, wherein the local void extends from a front surface of the encapsulation layer completely through the thickness of the encapsulation layer.

18. The process according to claim 15, wherein the encapsulation layer covers the electronic chip.

19. The process according to claim 15, wherein the local void has side edges and wherein elements of the surface electromagnetic antenna extend parallel to the side edges.
